(19) United States
(12) Patent Application Publication
(10) Pub. No.: US 2010/0309037 A1
(43) Pub. Date: Dec. 9, 2010

(54) SAMPLING COMPARATORS

(76) Inventor: Stephen Anthony Gerard Chandler, Gloucestershire (GB)

Correspondence Address: ROETZEL & ANDRESS, 1375 EAST 9TH STREET, CLEVELAND, OH, 44114, US

(21) Appl. No.: 12/865,204

(22) PCT Filed: Jan. 30, 2009
(86) PCT No.: PCT/GB09/50089

§ 371 Date: Aug. 25, 2010

(30) Foreign Application Priority Data
Jan. 30, 2008 (GB) 0801667.7
Jan. 31, 2008 (GB) 0801786.5

(51) Int. Cl. H03M 1/12; H03K 5/153

(52) U.S. Cl. 341/155; 327/73

(57) ABSTRACT

An improved regenerative clocked sampling circuit is described which uses a single clocking signal to switch the circuit between a tracking phase in which the state tracks the input signal, and a bistable phase during which the state rapidly approaches one of two states dependant on the input signal. The same clock signal also isolates the bistable circuit from the input signal source. In a preferred embodiment, these two actions are performed by the same transmission gate or gates connecting the input to the potentially bistable circuit.

### RELATED APPLICATIONS

This application claims priority to United Kingdom patent application no. 0801667.7, filed Jan. 30, 2008 and United Kingdom patent application no. 0801786.5, filed Jan. 31, 2008.

### FIELD OF THE INVENTION

This invention relates to improved sampling comparators for use in analogue-to-digital converters.

### BACKGROUND OF THE INVENTION

All digital-to-analogue converters require the comparison of a signal with at least one reference signal at specified sampling instants, usually at regular timing intervals, to produce a digital signal. For example, in “Flash” converters, as illustrated in FIG. 8, a multiplicity of such sampling converters, 117, simultaneously compare the signal, 110, at the sampling time provided by a clock source 111 with a multiplicity of reference signals which are normally uniformly spaced over the permitted range of signal values by division of a reference signal 112 with a chain of resistors 113. Combinational logic then converts this set of digital signals to a digital binary word for subsequent digital signal processing, storage or communications.

In successive approximation converters, the input signal is sampled and held as an analogue signal in a storage means, known as a sample hold or track store, is compared repeatedly, by means of a clocked comparator or flash converter with a reference signal obtained from a digital to analogue converter whose input derives from the output of the previous iteration of the conversion, and storing the result in a register. This may be implemented either by using the same circuit recursively, updating register during each iteration, or by using separate circuits for each stage of the iteration. This clearly has the advantage that if the residue or remaining error between the signal being measured and the signal represented by the digital value so far measured, is held in a sample hold to use as the input to the next stage, the first stage may then start digitising the next sample. This is the basic idea behind prior art pipeline analogue to digital converters.

Delta sigma converters, also called sigma delta converters, illustrated in FIG. 9, usually comprise a sampling comparator, 117, producing a stream of binary pulses, at well over the Nyquist rate, whose input comes from the output of a linear loop filter, 121, whose input is the difference between the input signal, 110, and the said sampling comparator output pulse stream 123. This forms a non-linear feedback loop which adjusts the pulse stream so that it matches the input signal over the pass-band of the loop filter. The digital output of the converter is obtained by decimation of the sampling comparator output bit stream by a digital filter. The comparator output bit stream has conceptually been passed through a 1 bit digital-to-analogue converter, the accuracy of which, i.e. the consistency of the pulse amplitudes, limits the overall converter accuracy. Clearly also, accuracy is enhanced by increasing the loop gain over the signal bandwidth, and by maximizing the over-sampling rate.

The quantization of all analogue-to-digital converters is achieved by means of implementing sampling comparators is to use some kind of high gain amplifier whose output saturates at signal levels within the voltage range accepted by logic circuits as either “1” or “0”. Such a circuit must be preceded or possibly, as in Flash converters, followed by some sampling and storage means to define the sampling instant according to a sampling clock signal, and ensure that the output is held at a constant value long enough for it to have finished being used by the subsequent circuitry. The analogue accuracy required of the digital output signal depends on the type of converter. In cases of flash converters the accuracy had only to be adequate to prevent ambiguity about whether the output is a “1” or a “0”. In the case of a successive approximation converter, variation in the comparator output voltage could cause some variation in the signal presented to the successive stage, resulting in errors. However these problems are small compared to that encountered in a sigma delta converter in which the output of the comparator which comprises the (digital) output bit stream is in fact also the (analogue) feedback signal compared with the input within the feedback loop. This can easily be the limiting factor in the performance of the converter, particularly at high sampling speeds. However the use of high gain multi-stage amplification required for this, causes its own problems: apart from the tendency to high frequency instability of high gain multi-stage amplifiers, the delay, silicon area and probably more importantly, power consumption increase in proportion to, the number of stages.

Instead of achieving the high gain required by means of a multi-stage amplifier, positive feedback may be used as in the conventional Schmitt trigger circuit. Such a prior art circuit to achieve this is shown in FIG. 10 from the classic textbook “CMOS Analogue Circuit Design” by P. E. Allen and D. R. Holberg (ISBN 0-03-006587-9). These have a transfer characteristic which displays hysteresis which, unless it is very small, this can causes errors and compromise performance. Such small amounts of hysteresis require a loop gain which very accurately equal to −1. The fact that the input signal is still connected to the bistable circuit could still have some effect on the output signal. As well as that, it would need to be followed by some digital clocked storage device to set the sampling instant and hold the digital value till required. A better solution is to combine the action of sampling with regeneration in a clocked regenerative sampler, as illustrated in FIG. 3. Clocked samplers, in fact, unlike Schmitt triggers, have no requirement to minimize the hysteresis in the interests of accuracy. In fact the larger the better as the last thing one wishes is for the state to change in the middle of being used by other circuits! Since the regenerative circuit rapidly approaches an attractor which would normally be a constant signal value (voltage or current), it would be unlikely to be affected by smaller, parasitic, feedback paths in the way that a high gain cascaded amplifier would, and would, in fact, act as a discrete time system.

The circuit in FIG. 2 could be made to perform in such a manner if the clock pulse were applied to point 11 to turn the circuit on and off in stead of the constant bias assumed in the text. However the loop gain achievable by this circuit is fairly low, as is indeed desirable in a Schmitt trigger to enable the circuit to be reset to the other state without and unnecessarily large dead band. Another disadvantage of this circuit is that the response of the circuit is rather slow, both due to the low loop gain, and also by the slow action of the P channel devices in the current mirrors which provide the cross coupling to effect the negative resistance load on the comparator transistors connected to the input, and the higher the gain of the mirrors, the slower are their open loop response.

For these reasons most sampled regenerative comparators use the simpler, faster, and higher loop gain bistable using two n channel devices with the bases of each connected to the collectors of the other, as with the cross connected CMOS inverters 108 and 109 in the otherwise somewhat complex prior art circuit in FIG. 3 from U.S. Pat. No. 6,037,890A1. With this clocking is provided primarily by turning on the bistable by means of transistor 102 while making simultaneous changes to the conduction states of 101, 103, 106 and 107.

A similar, and somewhat simplified and improved, sampled regenerative comparator is shown in FIG. 4 of US 2005242844. In this, as in the previous case, the input signal is a current rather than a voltage. The sampling instant is primarily determined by the opening of gate 36 which has up till then been short circuiting the drains 32 and 34. In a real circuit, gate 36, when conducting, has a finite resistance which determines the effective transconductance gain of the circuit while in the stable state. When the gate opens, the circuit becomes bistable and whichever gate is more positive to take to the positive rail and the other to the negative rail. However, the input would still be connected to the bistable throughout the regenerative phase were it not for the actions of gates 50, 54 and 60, which would not only cause “kick back” of the transient to the input being sampled, but also, not mentioned in the patent, small variations in the output voltage in the presence of large input signals. Much of the patent concerns the complexities and compromises involved in the timing of these various gates.

All clocked sampler circuits, whether regenerative or not, involve some delay between the sampling instant determined by the clock pulse, and the output signal being available for use. For many applications this does not in itself matter were it not for the fact that it limits the sampling rate of many analogue to digital circuits.

One way of reducing this limitation that is used to improve the speed of successive approximation analogue-to-digital converters is to implement recursive processing as in-line processing. This is what is done in the case of prior art pipeline converters as illustrated in FIG. 11. In this the conversion of the signal is performed in a number of stages wherein a first stage samples the signal in some sample hold or track store means digitizes this sample to a certain resolution which may be from one bit upwards. The residue, that is the difference between the actual signal sample and the value given by the digital output of the first stage, is then passed to a second similar stage, which performs a similar quantization of the said residue while the first stage performs quantization of a new sample. This means that a N stage pipeline will be processing N staggered samples at any one time, which is obviously N times as fast as waiting for the completion of processing of one sample before embarking on the next. The basic algorithm is similar to a successive approximation ADC, but with each iteration performed on its own hardware. Although the time to convert a particular sample is not reduced, the sampling rate is increased by a factor of N. In many cases this is more important than the delay.

### SUMMARY OF THE PRESENT INVENTION

According to the present disclosure and related inventions, there is provided a sampling comparator for use in an analogue-to-digital converter in the form of a two-phase clocked regenerative sampling comparator including an amplifier for receiving an input signal and a positive feedback circuit controllable by a clocking signal, wherein sampling is effected by a transition from a loop gain of a designed amount below unity in a first phase to a loop gain above unity in a second phase, while simultaneously isolating the input signal.

In accordance with another aspect of the disclosure and related inventions, there is provided a clocked sampling comparator which includes a multiplicity of elemental samplers coupled to a common input, a clock pulse generator for generating a plurality of clocking pulse streams for controlling the timing of the elemental samplers, the clocking pulse streams all being of the same frequency but being delayed with respect to one another, and a combiner for combining the output pulses streams of the elemental samplers.

These and other aspects of the disclosure and related inventions are herein described in further detail with reference to the accompanying drawings.

### DESCRIPTION OF THE DRAWINGS

In order that the invention may be more fully understood, reference will now be, by way of example, to the accompanying drawings, in which:

FIG. 1 shows a prior art sample hold circuit.

FIG. 2 shows a prior art Schmitt trigger regenerative comparator.

FIG. 3 shows another prior art clocked regenerative comparator.

FIG. 4 shows a further improved prior art clocked regenerative comparator.

FIG. 5 shows a conceptual block diagram to illustrate the invention and differentiate from prior art.

FIG. 6 shows a schematic diagram of an idealized preferred embodiment of the invention.

FIG. 7 shows a block diagram of a preferred embodiment of the invention.

FIG. 8 shows a simplified block diagram of a typical flash analogue-to-digital converter.

FIG. 9 shows a simplified block diagram of a typical delta sigma analogue-to-digital converter.

FIG. 10 shows a prior art Schmitt trigger regenerative comparator.

FIG. 11 illustrates the principle of a clocked sampler according to the invention.

FIG. 12 shows a flash converter according to the invention.

FIG. 13 shows a delta sigma converter according to the invention.

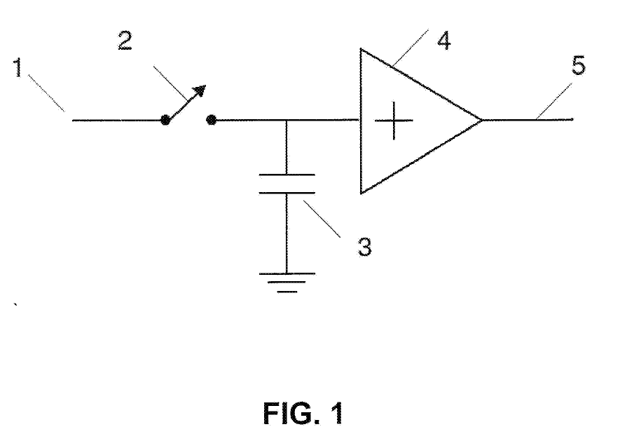

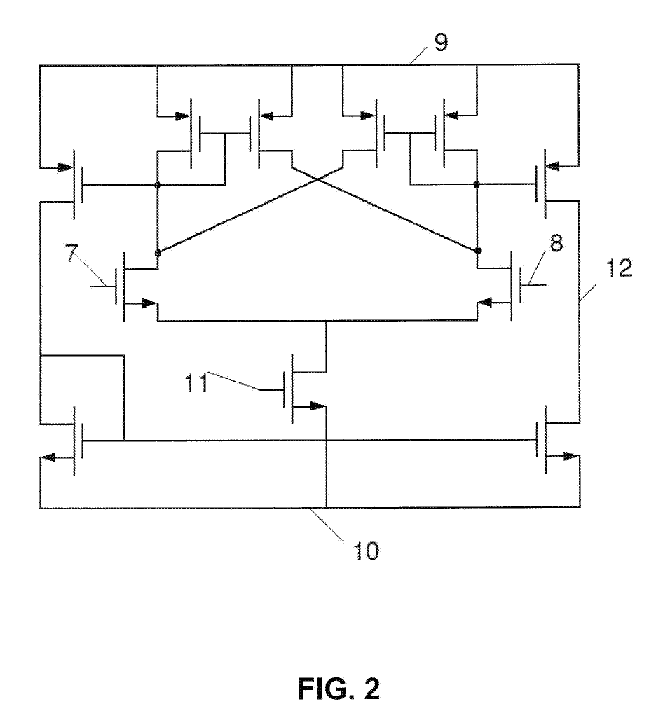

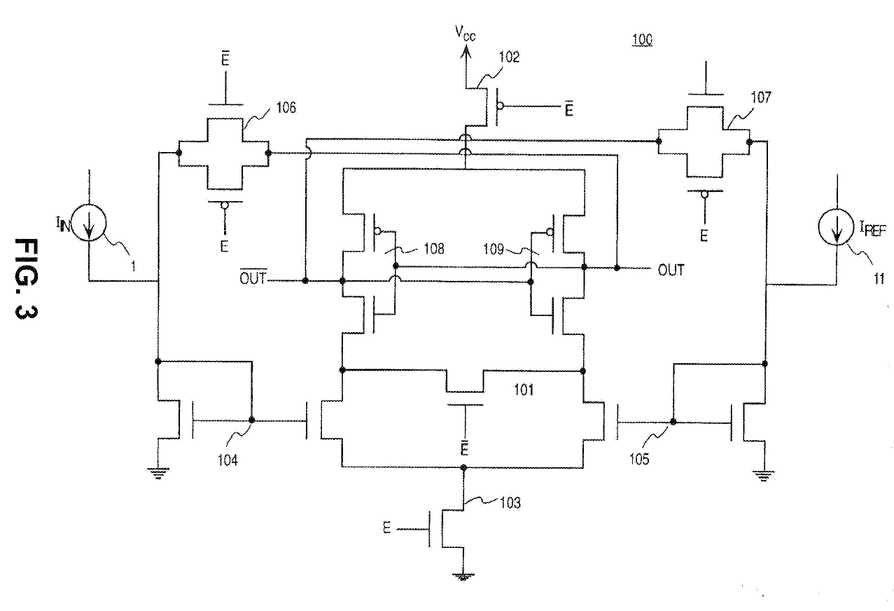

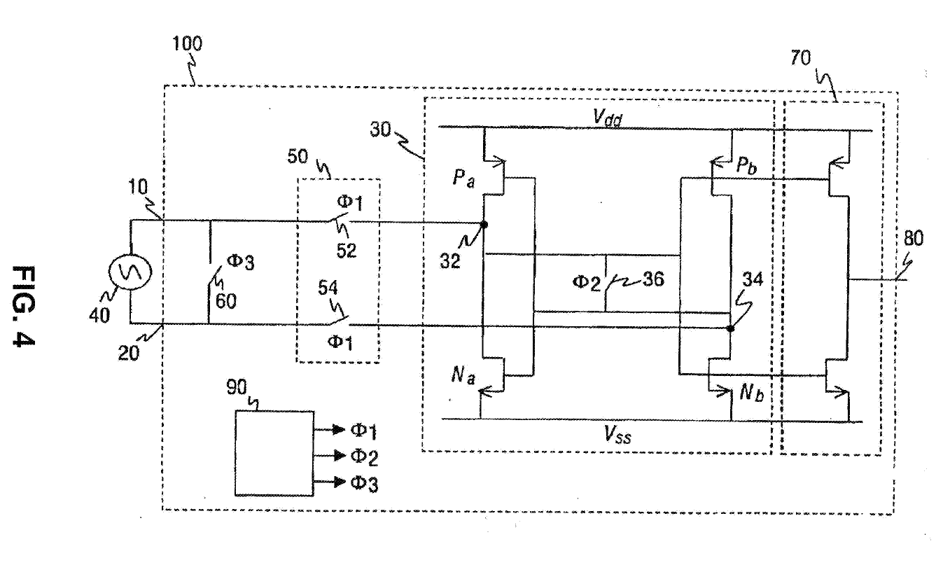

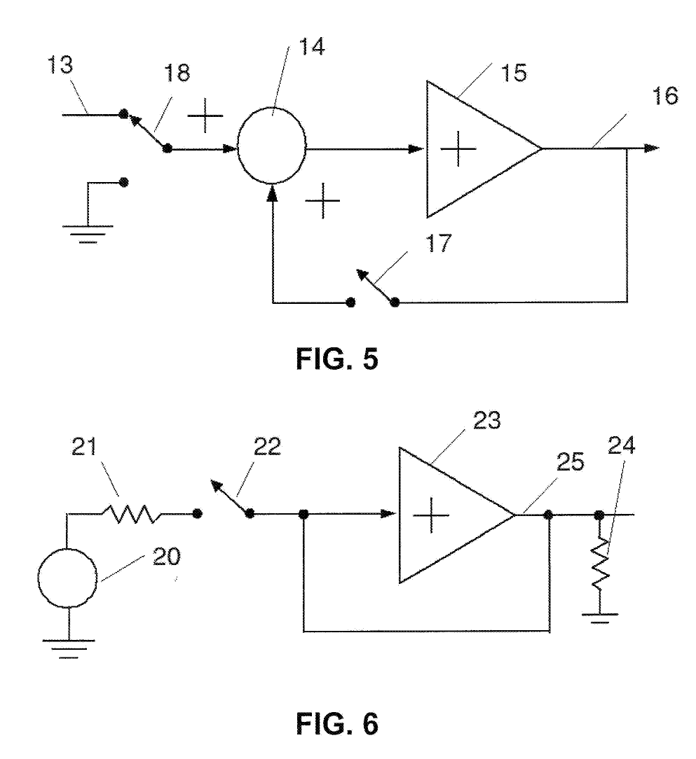

FIG. 5 shows a conceptual block diagram which illustrates a wide class of regenerative clocked samplers to which the invention belongs as well as the prior art mentioned above. An amplifying means 15 can receive its input from an external input 13 which is usually differential but for clarity shown here as a single signal, via some gating means 18. It may also receive a regenerative from its own output signal 16, again frequently differential, via another gating means 17. Amplifying means 15 will possess memory whereby its output will not change the instant it receives no input, in practice usually due to the effect of gate capacitance. Prior art clocked regenerative samplers function in two different ways: In the first signal 13 is enabled until the sampling instant followed after some interval of time by the enabling of the regenerative signal 16. In this case the action of gate 18 is that of a sample/hold as illustrated in FIG. 1, which is followed by regenerative amplification. The other way they operate is described in detail in the prior art from which FIG. 4 is taken. In this the sampling instant is defined as that at which regeneration is enabled by removing the short circuit effected by 30, which has the effect of 17 in FIG. 5. The input is then removed by 13 to prevent subsequent variations of input signal affecting the output 16. It is observed that the criterion for loop stability depends the finite on the ratio of the on conductance of 30 to the transconductance of the amplifying transistors. What is not observed is that in fact there may be benefits in terms of increasing sensitivity and speed in 30 not acting as a perfect short circuit. This is because the voltage on the gates of the active transistors, effectively the input to 15, is enhanced by the effect of some positive feedback prior to bistability. Upon the transition to bistability, these gate voltages act as initial condition to the initially exponential growth. This means that an amount proportional to the logarithm of this initial condition is in fact added to the settlement time of the comparator output.

What is taught herein is a two phase clocked regenerative sampling comparator comprising amplifying means and regeneration means controllable by a clocking signal, wherein the sampling is effected by the transition from loop gain of a designed amount below unity to one above unity. In the one phase, the tracking phase, the output state varies approximately linearly with the input signal, and in the other, the bistable phase, the output state approaches one of two limiting output values dependant on the state at the start of the phase.

A schematic diagram of a preferred embodiment of the invention is shown in FIG. 6 wherein 20 is an input signal source, 23 is a non-inverting transconductance amplifier, 24 a resistive load, 22 an ideal transmission gate means, 21 a series resistance comprising the on resistance of transmission gate 22 and internal resistance of signal source 20. I the value of 21 is R₁ and that of 24, R₂ and the transconductance of 23, gₘ, the condition for stability when the transmission gate 22 conducts is that

gₘ<1/R₁+1/R₂

when 22 becomes open circuit then obviously the criterion for stability is that

gₘ<1/R₂

or conversely if

gₘ>1/R₂

then the output will grow exponentially from its initial condition until the output voltage nears one of two limiting values. It is thus apparent that, when stopping, conduction transmission gate 20 performs three functions simultaneously and in a fast and predictable manner, i.e.
1. it defines the sampling instant by increasing the loop gain,
2. it prevents the input from having any further effect on the state of the bistable, and
3. it prevents the “kick-back” effects of the state transition of the bistable by isolating it from the input. It does this without the need for a further gate to short circuit the signal input, as is done by 60 in FIG. 4, relying instead on the low impedance of the signal source.

The loop gain is varied by a clock signal so that before the clock transition the loop gain is below unity, but after the transition the loop gain is above unity, making the circuit become bistable, i.e., having two stable attractors. This means that, if the signal exceeds the reference signal, the circuit state rapidly moves to one attractor, and, if the signal does not exceed the reference signal, the circuit state rapidly moves to the other attractor.

When this phase ends, and the circuit returns to the stable amplifying state, the circuit will take some time for the transient to subside and this obviously provides a minimum duration for this phase without which accuracy would be compromised for the next sample.

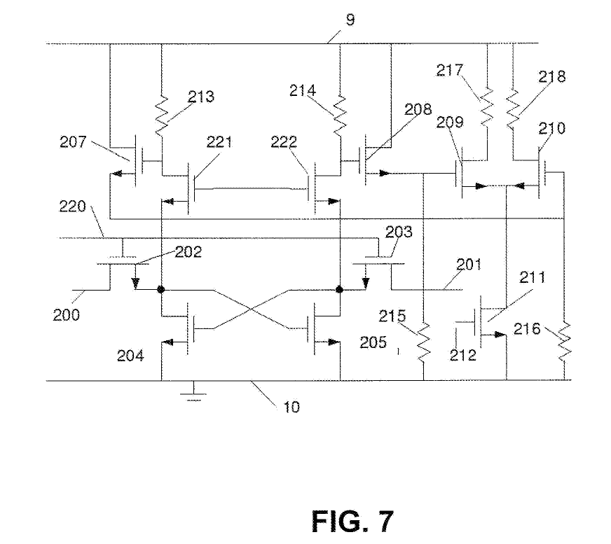

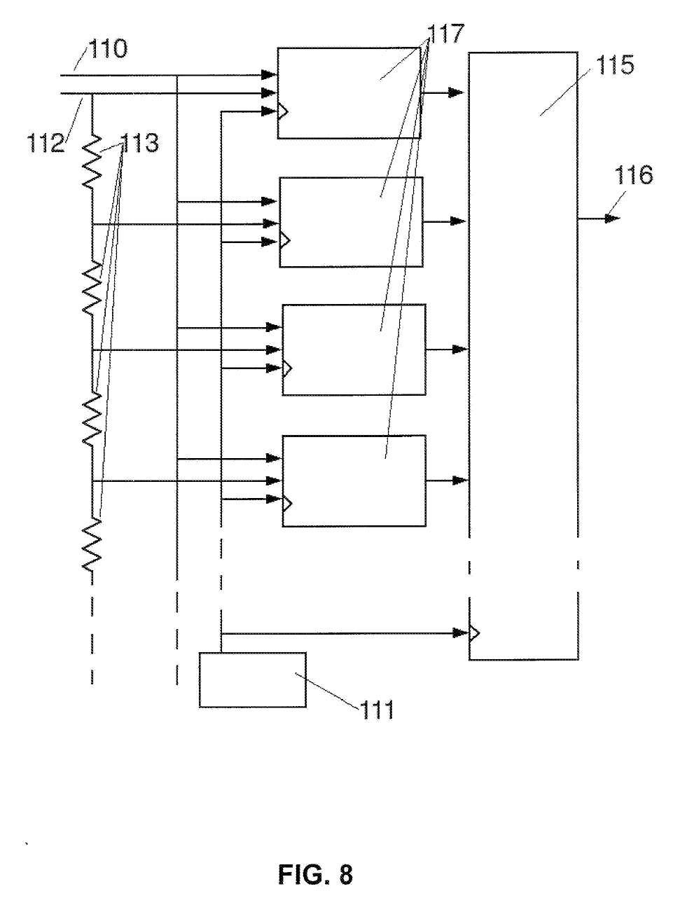

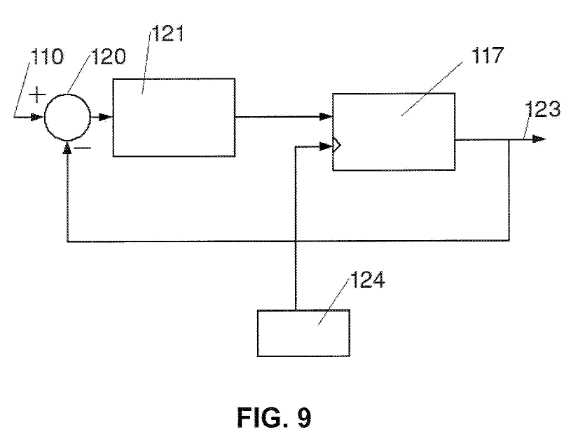

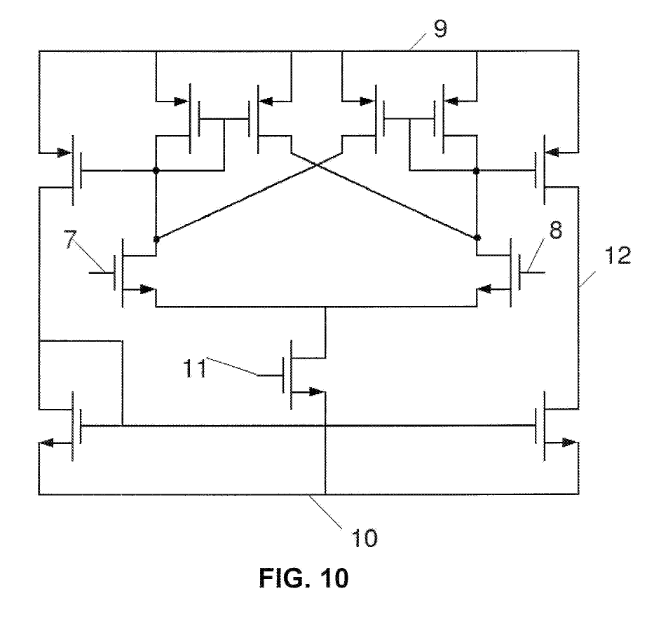

Although, in order to simplify the explanation, FIG. 6 shows the embodiment drawn as if it uses a single ended signal path, in fact in real life many benefits are obtained by using symmetrical differential circuits, and one such embodiment is illustrated in FIG. 7.

A preferred embodiment of the invention in a real application is shown in FIG. 7, in which 9 is the positive supply rail, 204 and 205 are transistors forming the basic bistable element, 202 and 203 are transmission gates connecting the differential input voltages 200 and 201 to the bistable. When a sufficiently positive voltage is applied at point 220, the transistors 202 and 203 conduct sufficiently, the circuit comprising 204 and 205 ceases to exhibit bistability and instead acts as a stable, somewhat regenerative differential amplifier as described above. This obviously requires that the impedance of the signal source has a sufficiently low impedance. Transistors 221 and 222 act as cascode amplifiers which, together with the source followers they drive, provide isolation from the following stage. 213 to 218 are loads which may be resistive or active circuits, such as complementary MOS transistors. The action of this following circuit is as follows. A pulse is supplied at 212 which turns transistor 211 on for a short time which finishes at or before the time the sampler changes from the bistable phase to the tracking phase. 209 and 210 act as a differential gate which routes this current pulse to either 217 or 218, depending on which of signals 200 and 201 is the larger.

What is also taught herein is sampling substantially the same signal 125 within the converter by a plurality of elemental sampling comparators 113 with the same input, each clocked by different clocking pulse streams of the same frequency but delayed with respect to each other generated by a generating means 124. In the preferred embodiments herein the pulses would be arranged so that the comparators would each sample in turn with the same time between successive samples. The samples from the comparators are then combined by a summing or combining means 122 to produce a pulse stream 123 at the rate of sampling of the individual samplers multiplied by the number of samplers. In the above description the term “substantially” is used to allow for the fact that it will normally be the case that the signal to be sampled will be buffered by some optional buffering, amplifying or other isolating means, and ideally identical means 126, before reaching each clocked sampler, to reduce any interaction between the individual elemental samplers.

In this the sampling comparators are in a pipeline to form the same function as a sampling comparator operating at N times the sampling rate. This type of pipelining is quite distinct from pipelining as referred to in the prior art in which the pipelined elements, themselves sampling comparators or flash converters, sample residues from previous stages.

One design issue which must be considered when using this approach is that, since different hardware is used for each of the N samples, care must be taken to ensure that the different offsets of the different component comparators do not cause undue amounts of signal, at the sample rate of the individual component comparators, in the digital output. This does not occur in single comparators as the offset error is the same for all measurements. This problem is of course mitigated by monolithic implementation of the circuit.

In a first, preferred, embodiment, the invention is applied to a flash converter as illustrated in FIG. 13. This is straightforward to understand, and is almost the same as N flash converters acting in parallel with staggered clocks. The difference is only that the same resistive divider network is used. What is achieved by it is just the increase in sampling rate, as opposed to prior art pipelining which achieves higher resolution as N is increased, but at the same sample rate.

In a second embodiment, a successive approximation converter is made by replacing the clocked comparators of a prior art pipelining ADC, as previously described, with multiple comparators with staggered clock pulses as taught by the invention.

In a third embodiment, a successive approximation converter is made by replacing flash converters of more than one bit resolution of a prior art pipelining ADC with flash converters comprising the first embodiment.

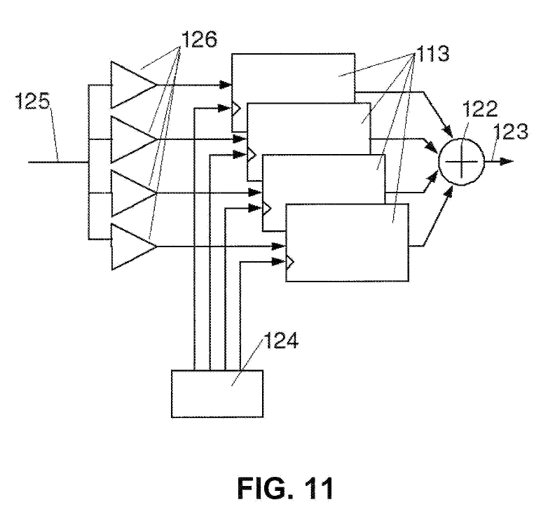

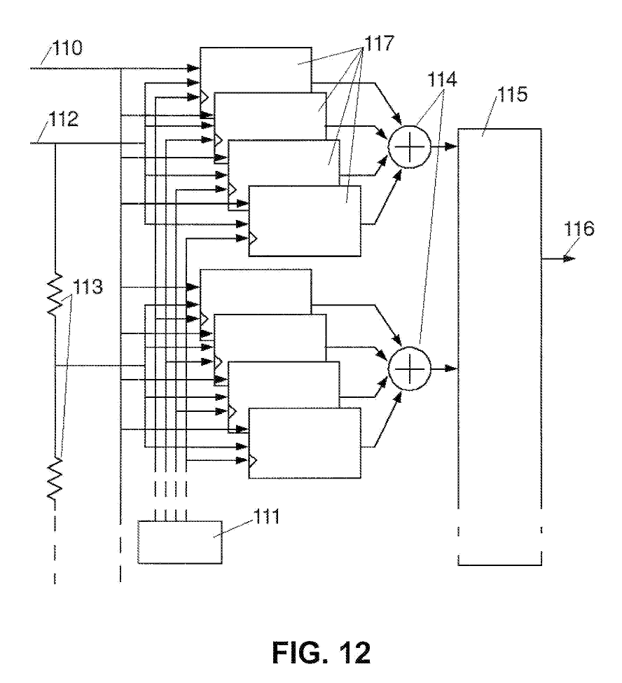

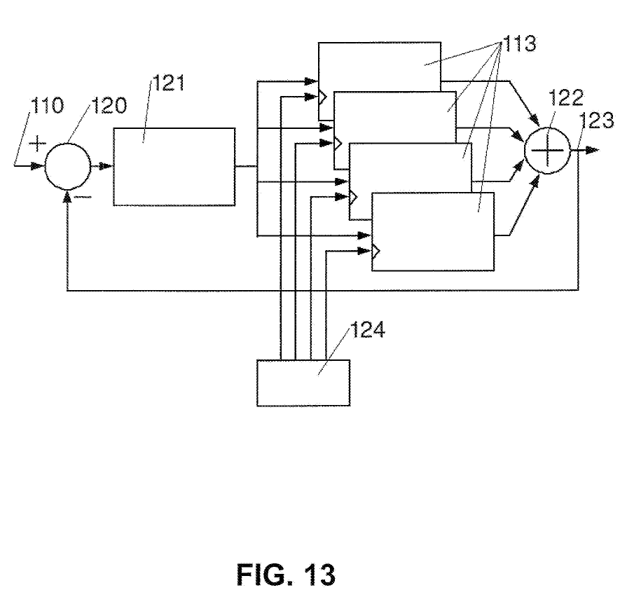

In a fourth embodiment illustrated in FIG. 11, a plurality of clocked comparators 113 with staggered clocks according to the invention, provided by clock generating means 124, are used as the comparator in a sigma delta converter (or delta sigma converter). This would increase the sampling rate by N, as usual. However it would not decrease the delay. With conventional comparators these two are inversely related and the benefits of increasing the sampling rate are attributable to both. The stability of sigma delta loops cannot be addressed by straightforward linear analysis as the action of the grossly non-linear, and indeed discontinuous, sampler is at the heart of the behaviour. The usual assumption is that the quantization noise which is the loop error signal uniform power spectral density is then added at the output of the filter to produce the comparator output. The total power in the output pulses is obviously constant, and so for a given input signal within the converter pass band, so is the quantisation noise. This noise power spectral density is then filtered by the loop by a function proportional to 1/∥1+βH(ω)c^{-jωT}∥², where H(ω) is the frequency response of the filter, and β is the feedback factor, and T the delay from the sampling instant to the centroid of the pulse. For maximum duration rectangular pulses producing a staircase waveform T must be larger than half the sampling period. This means that the noise is attenuated at frequencies at which the gain of the filter is high, but is boosted at frequencies at which the locus of βH(jω)e^{-jωT} passes close to −1. The signal output power, by contrast, varies as ∥H(jω)/1+βH(jω)e^{-jωT}∥², which remains reasonably constant if ∥↑H(ω)∥ exceeds unity by a reasonable amount. Note that these relations are derived solely from the linear elements in the model and exclude the comparator and do not involve the comparator. So, although it may look superficially similar, βH(jω) cannot be identified with the loop gain of a linear feedback loop and linear stability criteria are irrelevant. The system is thus designed such that the quantisation noise is moved from the passband, which is usually, but not necessarily, centred at zero frequency, to other frequencies at which it can be filtered out by anti-alias and decimation filters, a technique known as noise shaping. Clearly peaks in the noise spectral density near to the passband are to be avoided. These are more likely to occur with larger delays T, and so the benefits which might be expected from increasing the sampling rate of a conventional sampler may not be fully achieved using the technology proposed, but the improvements in noise shaping are still substantial.

There are significant extra benefits, though, in bandpass analogue-to-digital conversion. The fact that the technique can enable comparators based on conventional CMOS circuits to sample at GHz rates, as has been demonstrated in detailed. SPICE simulation, opens up the possibilities of direct conversion at radio frequencies without the need for high specification anti-alias filters, such as SAW filters, which cannot be tuned to different frequencies.

1. A two-phase clocked regenerative sampling comparator comprising an amplifier for receiving an input signal and a positive feedback circuit controllable by a clocking signal, wherein sampling is effected by a transition from a loop gain of a designed amount below unity in a first phase to a loop gain above unity in a second phase, while simultaneously isolating the input signal.

2. A comparator according to claim 1, wherein the positive feedback circuit is adapted to load the amplifier by the connection of the input signal during the first phase.

3. A comparator according to claim 1, wherein the positive feedback circuit is adapted to load the amplifier by connection of the input signal by one or more transmission gates.

4. A comparator according to claim 3, wherein the positive feedback circuit is adapted to load the amplifier by way of a transmission gate in the form of a MOS transistor.

5. A comparator according to claim 3, wherein the positive feedback circuit is adapted to load the amplifier by way of a transmission gate in the form of pair of complementary MOS transistors.

6. A clocked sampling comparator comprising a multiplicity of elemental samplers coupled to a common input, a clock pulse generator for generating a plurality of clocking pulse streams for controlling the timing of the elemental samplers, the clocking pulse streams all being of the same frequency but being delayed with respect to one another, and a combiner for combining the output pulses streams of the elemental samplers.

7. A comparator according to claim 6, wherein amplifying, isolating or buffering means are provided for connecting the input to the elemental samplers

8. A comparator according to claim 6, wherein the delays between successive clocking pulse streams are the same.

9. An analogue-to-digital converter including at least one clocked sampling comparator according to claim 6.

10. An analogue-to-digital converter according to claim 9, which is a sigma delta analogue-to-digital converter.

11. An analogue-to-digital converter according to claim 9, having a passband centred at some frequency other than zero.

12. A flash analogue-to-digital converter comprising means to generate multiple reference signals, a multiplicity of clocked sampling comparators according to claim 6 and timing pulse generator means.

13. A successive approximation pipeline analogue-to-digital converter comprising at least one clocked sampling comparator according to claim 6, and timing, differencing and buffering means.

14. A successive approximation pipeline converter comprising at least one flash converter according to claim 12 of more than one bit resolution, and timing, differencing and buffering and sample hold means.
